(19) United States
(12) Patent Application Publication
(10) Pub. No.: US 2025/0286352 A1
(43) Pub. Date: Sep. 11, 2025

(54) ELECTRICAL DISTRIBUTION SYSTEM AND METHOD

(71) Applicant: OGHJI, Nice (FR)

(72) Inventor: Pierre FOURLINNIE, Nice (FR)

(73) Assignee: OGHJI, Nice (FR)

(21) Appl. No.: 18/858,570

(22) PCT Filed: Apr. 20, 2023
(86) PCT No.: PCT/EP2023/060265

§ 371 Date: Oct. 21, 2024

(30) Foreign Application Priority Data
Apr. 22, 2022 (FR) FR2203739

(51) Int. Cl. H02B 1/20

(52) U.S. Cl. CPC H02B 1/20

(57) ABSTRACT

An electrical distribution system having a connection input coupled to a power supply line, an electrical distribution line, a controlled circuit breaker having an input terminal coupled to the connection input and an output terminal coupled to the electrical distribution line, controlled cut-off devices coupled to the electrical distribution line, electrical distribution outlets configured to power electrical circuits, and an electronic control unit configured to control the opening and closure of the cut-off devices. The system includes a controlled switch including two thyristors mounted in a head-to-tail fashion. The switch is coupled to the input and output terminals of the circuit breaker. The electronic control unit is configured to control the opening and closure of the switch and of the circuit breaker.

### TECHNICAL FIELD

The present invention relates to electrical distribution, and more particularly to low-voltage electrical distribution.

### PRIOR ART

Currently, low-voltage electrical distribution panels are used to manage and distribute electricity, for example in a home. By low voltage, it should be understood a voltage lower than 1,000 V in the alternating mode. These panels allow electrically connecting the electrical network using electrical circuits to equipment. These panels are complex because they generally comprise various protection devices, such as circuit breakers, differential with varied cut-off capacities, or contactors. In general, these devices operate autonomously, but could be controlled manually.

For example, mention may be made of the international application WO2014047733 which discloses systems for detecting short-circuit current faults in power transmission and distribution networks using several installations power generation installations based on inverters. These systems use inverters, which complicates the management of the distribution of the current.

Mention may also be made of the French patent application FR2819951, which discloses an electrical distribution system comprising a controlled cut-off device and four outlets. The device includes control means for controlling the cut-off device. Furthermore, the device includes current sensors and control means for controlling the opening of the outlets. Yet, in the event of a short-circuit on one outlet, the cut-off device opens and all outlets are no longer supplied with current.

Hence, the system does not allow isolating the faulty outlet so as to maintain a power supply of the other outlets that are not faulty.

One object consists in overcoming these drawbacks, and more particularly in providing simple means for limiting the power supply losses of the electrical equipment in the event of an electrical fault.

### SUMMARY

To achieve this objective, an electrical distribution system is provided, comprising a connection input intended to be coupled to a power supply line, an electrical distribution line, a controlled circuit breaker having an input terminal coupled to the connection input and an output terminal coupled to the electrical distribution line, controlled cut-off devices coupled to the electrical distribution line, electrical distribution outlets intended to power electrical circuits, each outlet being coupled to a cut-off device, and an electronic control unit configured to control the opening and the closure of the cut-off devices.

The system comprises a controlled switch comprising two thyristors mounted in a head-to-tail fashion, the switch being coupled to the input and output terminals of the circuit breaker, and in that the electronic control unit is further configured to control the opening and the closure of the switch and of the circuit breaker.

Thus, a simple electrical distribution system is provided, suitable for maintaining the power supply of the circuits that are not faulty, in particular in the event of a short-circuit on one single outlet.

According to another aspect, an electrical distribution method is provided, comprising coupling a connection input of an electrical distribution system, as defined hereinbefore, to a power supply line, coupling the electrical distribution outlets of the system to electrical circuits, and closing the circuit breaker and the cut-off devices of the system to power the electrical circuits.

### BRIEF DESCRIPTION OF THE FIGURES

The aims, objects, as well as the features and advantages of the invention will appear better from the detailed description of some embodiments and implementations of the latter, illustrated by the following appended drawings, wherein:

FIG. 1 schematically illustrates an embodiment of an electrical distribution system; and

FIG. 2 schematically illustrates another embodiment of an electrical distribution system.

The drawings are given as examples and do not limit the invention. They consist of schematic representations of principle intended to facilitate understanding of the invention and are not necessarily plotted to the scale of practical applications.

### DETAILED DESCRIPTION

Before starting a detailed review of embodiments and implementations of the invention, optional features that could possibly be used in combination or alternatively are set out hereinafter.
According to one example, the system comprises devices for measuring the currents flowing in the cut-off devices coupled to the electronic control unit, the electronic control unit being configured to control the opening of a cut-off device when the current flowing in the cut-off device is higher than or equal to a first fault current threshold and lower than or equal to a second fault current threshold, the second threshold being strictly higher than the first threshold.
According to one example, the electronic control unit is configured to control the opening of a cut-off device when the current flowing in the cut-off device is lower than or equal to a cut-off current threshold.
According to one example, the electronic control unit is configured to control the opening of the switch when the current flowing in the switch is lower than or equal to an opening current threshold.
According to one example, the electronic control unit is configured to control the opening of the circuit breaker, when a current flowing in a cut-off device is strictly higher than the second fault current threshold, to control the opening of the cut-off device, to control the closure of the switch after opening of the cut-off device, and to control the closure of the circuit breaker after opening of the cut-off device. Thus, thanks to such a sequence, it is possible to open the cut-off device without having to wait for the zero-crossing of the fault current. According to another advantage, the switch is closed before closing the circuit breaker in order to be able to power again the electrical circuits that are not faulty as fast as possible. Indeed, the closure of the controlled circuit breaker requires a reset time before closure thereof which could be longer than the closure time of the switch. For example, the reset time of the circuit breaker could amount to at least one second.
According to one example, the electronic control unit is configured to control the opening of the switch after closure of the circuit breaker.
According to one example, a first current of a first phase is intended to flow at the connection input, the system comprising a device for detecting a leakage current configured to measure a difference between the first current and a second current intended to power the electrical circuits and having a second phase distinct from that of the first current, the electronic control unit being configured, when a current difference is higher than or equal to a leakage current threshold, to control the opening, successively, of each cut-off device so as to determine the faulty cut-off device generating the current difference.
According to one example, the method comprises measuring the currents flowing in the cut-off devices, and opening a cut-off device when a current flowing in the cut-off device is higher than or equal to a first fault current threshold and lower than or equal to a second fault current threshold.
According to one example, opening a cut-off device is performed when the current flowing in the cut-off device is lower than or equal to a cut-off current threshold.
According to one example, opening the switch is performed when the current flowing in the switch is lower than or equal to an opening current threshold.
According to one example, the method comprises opening the circuit breaker, when a current flowing in a cut-off device is strictly higher than the second fault current threshold, then opening the cut-off device, then closing the switch, then closing the circuit breaker.
According to one example, the method comprises opening the switch after closure of the circuit breaker.
According to one example, a current of a first phase flows at the connection input, and the method comprises measuring a difference between the first current and a second current powering the electrical circuits and having a phase distinct from that of the first current, and comprising, when a current difference is higher than or equal to a leakage current threshold, successively opening each cut-off device so as to determine the faulty cut-off device generating the current difference.

It is specified that, in the context of the present invention, the expression “A coupled to B” or “A electrically coupled to B” is synonymous with “A is in electrical connection with B” and does not necessarily mean that there is no member between A and B. Thus, these expressions refer to an electrical connection between two elements, this connection could be direct or not, this means that it is possible that, between a first device A and a second device B that are electrically connected, a current flows in A, in B, and on the path connecting A to B, this path could comprise, or not, other electrical equipment.

Conversely, in the context of the present invention, the term “electrically connected directly” means a direct electrical connection between two elements. This means that, between a first device A and a second device B that are electrically connected directly, there is no other equipment, other than an electrical connection or several electrical connections.

It is specified that, in the context of the present invention, the term “electrically placed” or “electrically located” means a positioning of a device on a line in which a current flows.

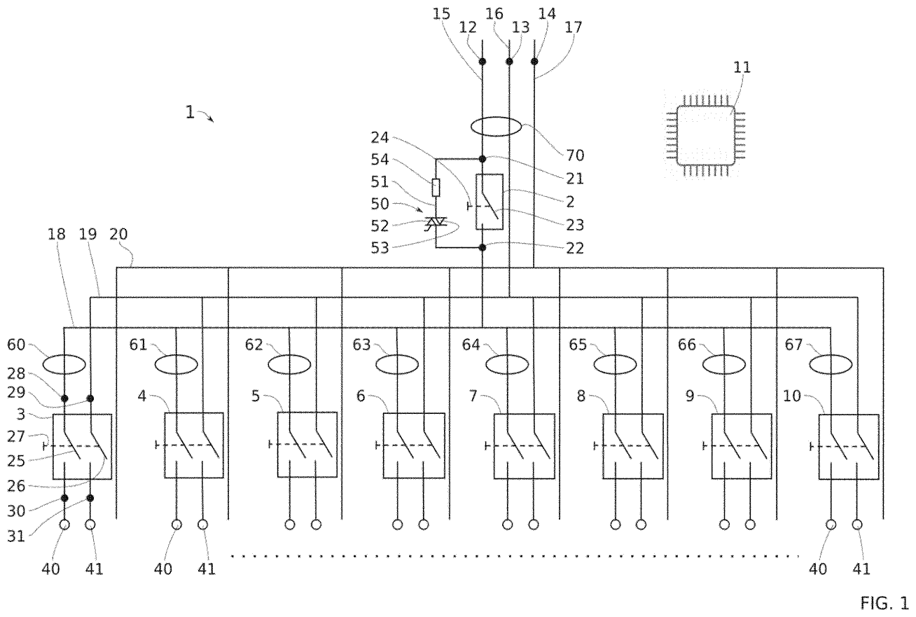

FIG. 1 shows an electrical distribution system 1, comprising a controlled circuit breaker 2, controlled cut-off devices 3 to 10 and an electronic control unit 11. Furthermore, the system 1 comprises first, second and third connection inputs 12 to 14 intended to be coupled respectively to three power supply lines 15 to 17. In general, the system 1 is adapted to distribute a single-phase alternating current, i.e. the system 1 is configured to be electrically coupled to two power supply lines 15, 16, and a line, so-called ground or mass line 17. A first power supply line 15 corresponds to the first line 15, so-called the phase line, the second power supply line 16 corresponds to the second line 16, so-called the neutral line. Thus, there is a phase and voltage difference between the two power supply lines 15, 16, in particular a voltage of about 230 V, and a voltage of about 0 V in the third line 17.

The system further comprises first, second and third electrical distribution lines 18 to 20 electrically coupled to the respective connection inputs 12 to 14. The circuit breaker 2 comprises an input terminal 21 coupled to the first connection input 12 and an output terminal 22 coupled to the first electrical distribution line 18. The circuit breaker 2 is configured to let the electric current, flowing in the first line 15, flow, and protect the downstream equipment from the damages caused by an excessive current, i.e. an overcurrent. By downstream equipment, it should be understood equipment electrically coupled to the output terminal 22 of the circuit breaker 2, for example the cut-off devices 3 to 10. In particular, the circuit breaker 2 includes a cut-off member 23 able to open to interrupt the current and protect the downstream equipment, and to close to let the current flow and power the downstream equipment. The circuit breaker 2 has an overcurrent cut-off capacity, i.e. it is configured to open in the event of an overcurrent without being deteriorated. The cut-off capacity is characterised by the maximum intensity of the current that would pass if no circuit breaker was interrupted. The cut-off capacity of the circuit breaker 2 may be higher than or equal to 3 kA, for example higher than or equal to 6 kA. In general, there are two types of overcurrent, a low overcurrent, for example an overload, and a high intensity, for example a short-circuit. An overload may be due to an overabundance of electrical equipment. A short circuit may correspond to an increase in the intensity beyond a triggering current defined by a triggering curve of the circuit breaker.

In general, a circuit breaker is triggered, i.e. opens the circuit, according to its characteristics according to a curve representing the triggering of the circuit breaker as a function of the intensity that crosses it and time, so-called triggering curve. In other words, the triggering curve refers to the graphical representation of the behaviour of the circuit breaker. The rated current In, denoted rated intensity, corresponds to the normal intensity that the circuit breaker can permanently withstand at room temperature. Beyond the rated current In (with a tolerance corresponding to 1.2*In), the circuit breaker is triggered and cuts off the current. Moreover, a circuit breaker can withstand a higher intensity, i.e. an intensity higher than 1.2*In, for a time period determined by the curve, in particular a very short time period. A triggering curve also has a limit corresponding to the magnetic triggering intensity (or triggering threshold). The magnetic triggering intensity varies according to the curve of the circuit breaker. In general, there are three types of curves B, C and D. Thus, when the overcurrent is lower than the magnetic triggering intensity, we talk about a low intensity and when the overcurrent is higher than or equal to the magnetic triggering intensity, we talk about a high overcurrent. This means that the low overcurrent is taken into account by the thermal protection of the circuit breaker 2, and the high overcurrent is taken into account by the magnetic protection of the circuit breaker 2. Thus, in the event of a high overcurrent, triggering should occur between 3*In and 5*In for a circuit breaker set in curve B, between 5*In and 10*In for a circuit breaker set in curve C, and between 10*In and 14*In for a circuit breaker set in curve D. A short circuit may be due to an accidental contact of two different potential points (for example between the phase and the neutral). Preferably, the circuit breaker 2 is magnetic, i.e. it includes a coil in which the current flows, which creates a magnetic field for moving the cut-off member 23 in the event of an overcurrent. More particularly, the circuit breaker 2 is controlled, i.e. it includes a control unit 24 configured to open and close the cut-off member 24 when it receives a command. The control unit 24 is electrically coupled, preferably directly, by a connection, which is not shown for simplicity, to the electronic control unit 11 which can transmit an opening and closure command to the control unit 24 of the circuit breaker 2.

The cut-off devices 3 to 10 are electrically coupled to the power supply lines 15, 16. As example, eight cut-off devices 3 to 10 have been shown in FIG. 1. For example, a cut-off device 3 to 10 is a switch comprising a movable element 25, 26 for opening and closing a circuit. A cut-off device 3 to 10 may be an electromechanical relay, i.e. a piece of electrical equipment comprising a control portion 27 for emitting a closure or opening command to one or two movable element(s) 25, 26 of the cut-off device 3 to 10. A cut-off device 3 to 10 may be a bipolar contactor, preferably bistable. Moreover, each cut-off device 3 to 10 is controlled, i.e. each control portion 27 is electrically coupled, preferably directly, by a connection, which is not shown for simplicity, to the electronic control unit 11 which can transmit an opening and closure command to the control portion 27 of the cut-off device 3 to 10.

A cut-off device 3 to 10 is particular in that it has a low cut-off capacity strictly lower than that of the circuit breaker 2. For example, a cut-off device has a cut-off capacity lower than or equal to 50 A. This means that it is not possible to control the opening of the movable element 25, 26 when a current higher than or equal to a cut-off current threshold flows in the movable element 25, 26 in the closed position. Preferably, the cut-off current threshold is close to 0 A. In other words, to open a cut-off device 3 to 10, the current that flows in the device should be lower than or equal to the cut-off current threshold. Such cut-off devices are simpler than circuit breakers, which simplifies the system 1. In general, each cut-off device 2 comprises at least one movable element 25, 26, at least one input terminal 28, 29 electrically coupled to at least one distribution line amongst the first and second distribution lines 18, 19, and at least one output terminal 30, 31, electrically coupled to at least one movable element 25, 26. Thus, a cut-off device 3 to 10 may include one single movable element 25 electrically coupled to a first input terminal 28 and to a first output terminal 30 for opening or closing the first distribution line 18. Advantageously, a cut-off device 2 comprises two movable elements 25, 26 coupled respectively to the input terminals 28, 29 and to the output terminals 30, 31 of the cut-off device 3 to 10. In this case, a first movable element 25 can open and close the first distribution line 18 and a second movable element 26 can open and close the second distribution line 19. More particularly, the cut-off devices are controlled

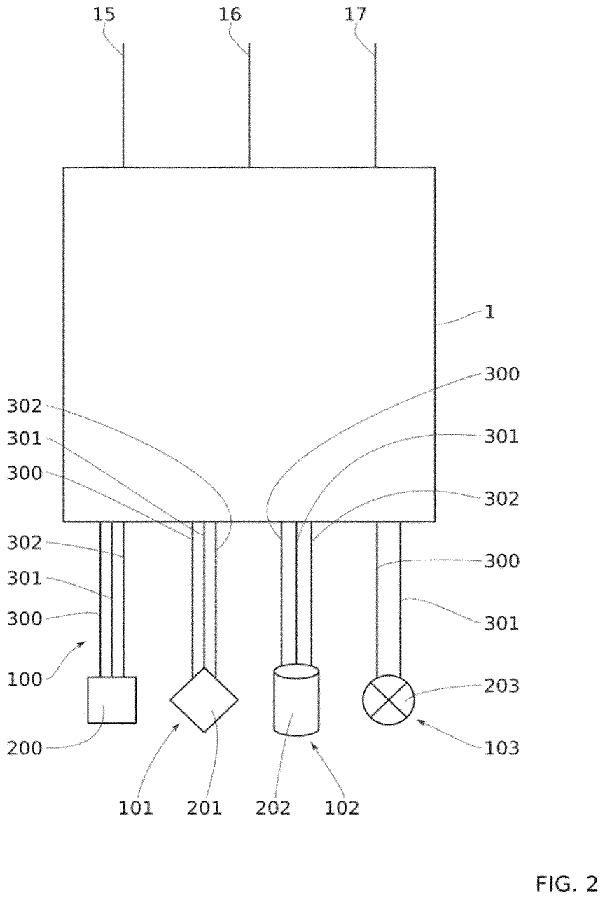

Moreover, the system 1 comprises electrical distribution outlets 40, 41. Each outlet 40, 41 is intended to power an electrical circuit 100 to 103 comprising one or more piece(s) of electrical equipment 200 to 203, as illustrated in FIG. 2. Each outlet 40, 41 is also electrically coupled, preferably directly, to an output terminal 30, 31, of a cut-off device 3 to 10. FIG. 2 shows an electrical distribution system 1 which is particularly suitable for a domestic network, i.e. a network powered by a single-phase alternating current. As example, a first circuit 100 comprising a washing machine 200, a second circuit 101 comprising an air-conditioner 201, a third circuit 102 comprising a water heater 202 and a fourth circuit 103 comprising an electrical socket 203, for example intended to be coupled to a lamp, are shown. Each electrical circuit 100 to 103 comprises at least two conductors 300, 301 intended to be electrically coupled, preferably directly, respectively to two outlets 40, 41 of the system 1. In other words, each electrical circuit 100 to 103 comprises two conductors 300, 301 electrically coupled to the output terminals 30, 31 of a cut-off device 3 to 10. According to another example, an electrical circuit 102 may comprise a third conductor 302, so-called ground conductor, coupled to the third distribution line 20.

The electronic control unit 11 is configured to control the opening and the closure of the cut-off devices 3 to 10. The electronic control unit 11 may comprise a microprocessor. Preferably, the electronic control unit 11 comprises a microcontroller able to rapidly perform computations to control the cut-off devices 3 to 10 as fast as possible.

More particularly, the electronic control unit 11 is configured to control the opening and the closure of the circuit breaker 2. Furthermore, the system 1 comprises a controlled switch 50 coupled to the input 21 and output 22 terminals of the circuit breaker 2. In other words, the switch 50 is mounted in parallel with the circuit breaker 2, i.e. it is mounted on a line 51 parallel to the circuit breaker 2. The switch 50 is further configured to open or close the parallel line 51 to respectively prevent and enable a flow of the current in the parallel line 51 between the input terminal 21 and the output terminal 22 of the circuit breaker 2. The switch 50 is also electrically coupled, preferably directly, by a connection, which is not shown for simplicity, to the electronic control unit 11 which can transmit an opening and closure command to the switch 50. More particularly, the switch 50 comprises two thyristors 52, 53 mounted in a head-to-tail or anti-parallel fashion, such a switch is also so-called a triac (or Triode for alternating current). A thyristor is a three-terminal semiconductor electronic switch, i.e. comprising four silicon layers alternately doped by acceptors (P) and donors (N). A thyristor includes two main terminals, denoted anode and cathode, located on either side of the four PNPN layers. The third terminal, so-called trigger, is used to control the thyristor. The third terminal is electrically coupled to the P layer located on the cathode side. The thyristors 52, 53 of a triac are mounted in a head-to-tail fashion, i.e. in an anti-parallel fashion, i.e. the anode of a thyristor 52, 53 is coupled directly to the cathode of the other thyristor 53, 52. More specifically, the anode of a first thyristor 52 is coupled directly to the cathode of a second thyristor 53 and the anode of the second thyristor 53 is coupled directly to the cathode of the first thyristor 52. Moreover, their respective triggers are controlled simultaneously. The triac is closed by a closure command applied on the triggers of the two thyristors 52, 53 and lets the current pass as long as the current is higher than or equal to a threshold so-called the holding current (in general, the holding current is equal to 0.65 A). The closure command may be pulsed because the current that crosses the triac no longer depends on the command applied on the triggers. In other words, the triac remains conducting until the current flowing between the input terminal 21 and the output terminal 22 falls below the value of the holding current. Preferably, and in order to guarantee the closed state of the triac, the closure control is applied continuously on the triggers when it is desired to close the triac. An opening command applied on the triggers opens the triac that is no longer conducting. Advantageously, the parallel line 51 may comprise a resistor 54 located between the input terminal 21 and the switch 50. The resistor 54 is also so-called current limiter resistor. A triac offers the advantage of having a small volume, smaller than or equal to 1 cm3, which allows having a more compact system 1. According to another advantage, a triac has a faster closure speed than an electromechanical relay. For example, a triac may have a closure speed lower than or equal to 1 ms. Thus, it is possible to re-supply the electrical circuits with power as fast as possible after opening of the circuit breaker 2.

In general, the system 1 is adapted to manage the power supply of a plurality of electrical circuits, using at least one circuit breaker 2 and one switch 50, in particular in the event of an overcurrent, which makes the system simple and effective.

Advantageously, the system 1 comprises measuring devices 60 to 67 for measuring the currents flowing in the cut-off devices 3 to 10. For example, a measuring device 60 to 67 may comprise a resistor electrically coupled between an input terminal 28, 29 of a cut-off device 3 to 10 and a connection input 12 to 14, depending on the current to be measured. Preferably, a measuring device 60 to 67 comprises a resistor electrically coupled between the first input terminal 28 of a cut-off device 3 to 10 and the output terminal 22 of the circuit breaker 2, in order to measure the current flowing in the first distribution line. Alternatively, a measuring device 60 to 67 may comprise a Hall-effect sensor electrically coupled between an input terminal 28, 29 of a cut-off device 3 to 10 and a connection input 12 to 14. Furthermore, the measuring devices 60 to 67 are electrically coupled, preferably directly, by connections which are not shown for simplicity, to the electronic control unit 11. Thus, the electronic control unit 11 can control the circuit breaker 2, the cut-off devices 3 to 10 and the switch 50, depending on the values of the currents flowing in the cut-off devices 3 to 10, i.e. in the electrical circuits coupled to the cut-off devices 3 to 10.

For example, in the event of an overcurrent due to an overload in a cut-off device 3 to 10, it is also said that the cut-off device 3 to 10 is faulty, and the electronic control unit 11 is configured to control the opening of the faulty cut-off device. In particular, the electronic control unit 11 receives the measurement of an overload current transmitted by the measuring device 60 to 67 which is coupled to the faulty cut-off device 3 to 10. When the current flowing in the faulty cut-off device 3 to 10 is higher than or equal to a first fault current threshold and lower than or equal to a second fault current threshold, the electronic control unit 11 controls the opening of the faulty cut-off device 3 to 10. The second threshold is strictly higher than the first threshold. For example, the first fault current threshold may be equal to 10*In and the second fault current threshold may be equal to 1,000*In. For example, the rated current In may be equal to 32 A.

Advantageously, the electronic control unit 11 is configured to control the opening of a cut-off device 3 to 10 when the current flowing in the cut-off device 3 to 10 is lower than or equal to a cut-off current threshold. The cut-off current threshold may be equal to the cut-off capacity of the cut-off device 3 to 10. For example, the cut-off current threshold may be lower than or equal to 50 A, for example comprised between 0.1 and 0.5 A.

For example, in the event of a high overcurrent, for example a short-circuit, in a cut-off device 3 to 10, it is also said that the cut-off device 3 to 10 is faulty, and the electronic control unit 11 is configured to control the opening of the circuit breaker 2. In particular, the electronic control unit 11 receives the measurement of a high intensity current transmitted by the measuring apparatus 60 to 67 which is coupled to the faulty cut-off device 3 to 10. When the current flowing in the faulty cut-off device 3 to 10 is strictly higher than the second fault current threshold, the electronic control unit 11 controls the opening of the circuit breaker 2. Then, the electronic control unit 11 controls the opening of the faulty cut-off device 3 to 10, in order to electrically isolate the electrical circuit coupled to the faulty cut-off device. It should be noted that since the circuit breaker 2 is open, there is no current flowing in the cut-off devices, in particular on the distribution line electrically coupling the output terminal of the circuit breaker 2 and the movable element 25, and it is therefore possible to control the opening of the movable element 25 without waiting for the zero-crossing of the current. The zero-crossing of the current corresponds to the fact that the current flowing in one amongst the first and second distribution lines 18, 19 is lower than or equal to the cut-off current threshold. Preferably, in the case where a cut-off device 3 to 10 comprises two movable elements 25, 26, we wait for the zero-crossing of the current flowing in the second distribution line 19 to control the opening of the second movable element 26. Preferably, when a cut-off device 3 to 10 comprises two movable elements 25, 26, by controlling the opening and the closure of the cut-off device 3 to 10, it should be understood the opening and the closure of the two movable elements 25, 26 of the cut-off device 3 to 110. Then, the electronic control unit 11 controls the closure of the switch 50, in order to power the electrical circuits that are not faulty. In particular, the electronic control unit 11 is electrically coupled upstream of the circuit breaker 2 in order to be able to control the switch 50, in particular closure thereof, after an opening of the circuit breaker 2. In other words, the electronic control unit 11 is electrically coupled to the connection inputs 12 to 14 and to the power supply lines 15 to 17 for electric power supply thereof. Advantageously, the electronic control unit 11 is configured to control the opening of the switch 50 when the current flowing in the switch 50 is lower than or equal to an opening current threshold. The opening current threshold may be higher than or equal to the cut-off current threshold of the cut-off devices 3 to 10. For example, the opening current threshold is lower than or equal to 50 A, preferably comprised between 0.1 A and 0.5 A. Then, the electronic control unit 11 controls the closure of the circuit breaker 2, in order to set the protection, in particular the protection against high overcurrents, in operation again. Advantageously, the electronic control unit 11 is configured to control, after the closure of the circuit breaker 2, the opening of the switch 50, in particular to avoid letting a power supply current flow in the switch 50 and thus limit wearing of the switch 50.

According to another advantage, the system 1 may comprise a device 70 for detecting a leakage current configured to measure a difference between a first current flowing in the first power supply line 15 and a second current flowing in the second power supply line 16. A leakage current corresponds to a current difference (in ampere) between the two power supply lines 15, 16. The detection device 70 is electrically coupled, preferably directly, by a connection, which is not shown for simplicity, to the electronic control unit 11. The electronic control unit 11 is configured to receive the value of the leakage current detected by the detection device 70. Moreover, when the electronic control unit 11 receives, from the detection device 70, a leakage current higher than or equal to a leakage current threshold, the electronic control unit is configured to determine the faulty cut-off device corresponding to the cut-off device 3 to 10 that is coupled to the electrical circuit that generates the leakage current. When the faulty cut-off device 3 to 10 is determined, the electronic control unit 11 controls the opening of the faulty cut-off device.

For example, to determine the faulty cut-off device 3 to 10, the electronic control unit 11 is configured to control the opening, successively, of each cut-off device 3 to 10. Thus, it is possible to determine the faulty cut-off device generating the current difference. More particularly, the electronic control unit 11 controls the opening of a first cut-off device 3 to 10, and if the leakage current disappears, i.e. if the current detected by the detection device 70 is strictly lower than the leakage current threshold, the cut-off device 3 to 10 that is open corresponds to the faulty cut-off device. Otherwise, the electronic control unit 11 controls the closure of the cut-off device 3 to 10 that is open and controls the opening of a second cut-off device 3 to 10 and again compares the current detected by the detection device 70 with the leakage current threshold. The electronic control unit 11 performs the previous operations, namely opening a cut-off device, comparing the detected leakage current with the leakage current threshold, until determining the faulty cut-off device for which the detected leakage current is strictly lower than the leakage current threshold. An electrical distribution method may be implemented by the system 1 as defined hereinbefore.

Advantageously, the system that has just been described allows managing overload overcurrent and short-circuit defects and leakage currents using a suitable electronic control unit. Thanks to such an electronic control unit, it is possible to use protection appliances that are simple to provide an electrical distribution system that is not very complex while guaranteeing effective protection for the electrical circuits and people.

1. An electrical distribution system, comprising a connection input for coupling to a power supply line, an electrical distribution line, a circuit breaker to be controlled and having an input terminal coupled to the connection input and an output terminal coupled to the electrical distribution line, cut-off devices to be controlled and coupled to the electrical distribution line, electrical distribution outlets for powering electrical circuits, each outlet being coupled to a cut-off device, and an electronic control unit configured to control the opening and the closure of the cut-off devices, wherein the system comprises a switch to be controlled and comprising two thyristors mounted in a head-to-tail fashion, the switch being coupled to the input and output terminals of the circuit breaker, and the electronic control unit is further configured to control the opening and the closure of the switch and of the circuit breaker.

2. The system according to claim 1, further comprising current measuring devices for measuring the currents flowing in the cut-off devices coupled to the electronic control unit, the electronic control unit being configured to control the opening of a cut-off device when the current flowing in the cut-off device is higher than or equal to a first fault current threshold and lower than or equal to a second fault current threshold, the second threshold being higher than the first threshold.

3. The system according to claim 2, wherein the electronic control unit is configured to control the opening of a cut-off device when the current flowing in the cut-off device is lower than or equal to a cut-off current threshold.

4. The system according to claim 2, wherein the electronic control unit is configured to control the opening of the switch when the current flowing in the switch is lower than or equal to an opening current threshold.

5. The system according to claim 2, wherein, the electronic control unit is configured to control the opening of the circuit breaker, when a current flowing in a cut-off device is higher than the second fault current threshold, to control the opening of the cut-off device, to control the closure of the switch after opening of the cut-off device, and to control the closure of the circuit breaker after opening of the cut-off device.

6. The system according to claim 5, wherein the electronic control unit is configured to control the opening of the switch after closure of the circuit breaker.

7. The system according to claim 1, wherein during operation of the system a first current of a first phase flows at the connection input, the system comprising a detection device of a leakage current configured to measure a difference between the first current and a second current for powering the electrical circuits and having a second phase distinct from that of the first current, the electronic control unit being configured, when a current difference is higher than or equal to a leakage current threshold, to control the opening, successively, of each cut-off device so as to determine the faulty cut-off device generating the current difference.

8. An electrical distribution method, comprising coupling a connection input of an electrical distribution system according to claim 1 to a power supply line, coupling the electrical distribution outlets of the system to electrical circuits, and closing the circuit breaker and the cut-off devices of the system to power the electrical circuits.

9. The method according to claim 8, comprising measuring the currents flowing in the cut-off devices, and opening of a cut-off device when a current flowing in the cut-off device is higher than or equal to a first fault current threshold and lower than or equal to a second fault current threshold.

10. The method according to claim 9, wherein opening a cut-off device is performed when the current flowing in the cut-off device is lower than or equal to a cut-off current threshold.

11. The method according to claim 8, wherein opening the switch is performed when the current flowing in the switch is lower than or equal to an opening current threshold.

12. The method according to claim 9, comprising opening the circuit breaker, when a current flowing in a cut-off device is higher than the second fault current threshold, then opening the cut-off device, and then closing the switch, and then closing the circuit breaker.

13. The method according to claim 12, comprising opening the switch after closure of the circuit breaker.

14. The method according to claim 8, wherein a current of a first phase flows at the connection input, the method comprising measuring a difference between the first current and a second current powering the electrical circuits and having a phase distinct from that of the first current, and comprising, when a current difference is higher than or equal to a leakage current threshold, successively opening each cut-off device so as to determine the faulty cut-off device generating the current difference.
